(19) United States
(12) Patent Application Publication
(10) Pub. No.: US 2026/0173935 A1
(43) Pub. Date: Jun. 18, 2026

(54) PACKAGE SUBSTRATE AND SEMICONDUCTOR PACKAGE INCLUDING THE SAME

(71) Applicant: Samsung Electronics Co., Ltd., Suwon-si (KR)

(72) Inventor: Jihan Ko, Suwon-si (KR)

(21) Appl. No.: 19/367,877

(22) Filed: Oct. 24, 2025

(30) Foreign Application Priority Data
Dec. 12, 2024 (KR) 10-2024-0184536

(51) Int. Cl. H01L 23/498; H01L 23/00; H01L 23/31; H01L 25/03; H01L 25/07

(52) U.S. Cl. CPC H10W 70/69; H10W 74/117; H10W 90/00; H10W 90/754

(57) ABSTRACT

A package substrate includes a base structure having first and second surfaces opposite to each other; a first protective layer on the first surface, wherein the first protective layer includes first organic and first inorganic insulation structures, and wherein the first organic insulation structure includes a first organic insulating material, and the first inorganic insulation structure includes a first inorganic insulating material; and a second protective layer on an upper surface of the first protective layer, wherein the second protective layer includes second organic and second inorganic insulation structures, and wherein the second organic insulation structure includes a second organic insulating material, and the second inorganic insulation structure includes a second inorganic insulating material, wherein a weight percent of the second inorganic insulating material with respect to the second protective layer is less than a weight percent of the first inorganic insulating material with respect to the first protective layer.

### CROSS-REFERENCE TO RELATED APPLICATIONS

This application claims priority under 35 U.S.C. § 119 to Korean Patent Application No. 10-2024-0184536, filed on Dec. 12, 2024 in the Korean Intellectual Property Office (KIPO), the contents of which are herein incorporated by reference in their entirety.

### BACKGROUND OF THE INVENTION

Example embodiments relate to package substrates and semiconductor packages including the same.

Solder resist (SR) for protecting upper and lower surfaces of a PCB may include an organic insulating material such as epoxy, and further include a filler such as silica, alumina, etc., in order to increase the strength (e.g., the stiffness and/or the hardness) of the SR. The filler may have a (substantially) spherical shape or a (substantially) hemispherical shape and may be disposed in an inside and/or on a surface of an organic insulating layer (including the organic insulating material). If the filler is disposed on the surface of the organic insulating layer, the surface roughness of the SR may increase.

### SUMMARY OF THE INVENTION

Example embodiments may provide a package substrate having enhanced electrical characteristics.

Example embodiments may provide a semiconductor package having enhanced electrical characteristics.

According to example embodiments, there is provided a package substrate. The package substrate may include a base structure having a first surface and a second surface that are opposite to each other in a direction that is perpendicular to the first surface and the second surface; a first protective layer on the first surface of the base structure, wherein the first protective layer includes a first organic insulation structure and a first inorganic insulation structure, and wherein the first organic insulation structure includes a first organic insulating material, and the first inorganic insulation structure includes a first inorganic insulating material; and a second protective layer on an upper surface of a portion of the first protective layer, wherein the second protective layer includes a second organic insulation structure and a second inorganic insulation structure, and wherein the second organic insulation structure includes a second organic insulating material, and the second inorganic insulation structure includes a second inorganic insulating material, wherein a weight percent of the second inorganic insulating material with respect to the second protective layer is less than a weight percent of the first inorganic insulating material with respect to the first protective layer.

According to example embodiments, there is provided a package substrate. The package substrate may include a base structure having a first surface and a second surface that are opposite to each other in a direction that is perpendicular to the first surface and the second surface; a first protective layer on the first surface of the base structure, wherein the first protective layer includes a first organic insulation structure and a first inorganic insulation structure, and wherein the first organic insulation structure includes a first organic insulating material, and the first inorganic insulation structure includes a first inorganic insulating material; and a second protective layer on an upper surface of a portion of the first protective layer, wherein the second protective layer includes a second organic insulation structure and a second inorganic insulation structure, and wherein the second organic insulation structure includes a second organic insulating material, and the second inorganic insulation structure includes a second inorganic insulating material, wherein a roughness of an upper surface of the second protective layer is less than a roughness of an upper surface of the first protective layer.

According to example embodiments, there is provided a semiconductor package. The semiconductor package may include a package substrate including: a base structure having a first surface and a second surface that are opposite to each other in a direction that is perpendicular to the first surface and the second surface; a first protective layer on the first surface of the base structure, wherein the first protective layer includes a first organic insulation structure and a first inorganic insulation structure, and wherein the first organic insulation structure includes a first organic insulating material, and the first inorganic insulation structure includes a first inorganic insulating material; and a second protective layer on an upper surface of a portion of the first protective layer, wherein the second protective layer includes a second organic insulation structure and a second inorganic insulation structure, wherein the second organic insulation structure includes a second organic insulating material, and the second inorganic insulation structure includes a second inorganic insulating material, wherein a weight percent of the second inorganic insulating material with respect to the second protective layer is less than a weight percent of the first inorganic insulating material with respect to the first protective layer, and wherein a roughness of an upper surface of the second protective layer is less than a roughness of an upper surface of the first protective layer; a first semiconductor chip on the package substrate; an underfill member between the upper surface of the second protective layer and a lower surface of the first semiconductor chip; and a molding member on the first semiconductor chip and the underfill member.

In the semiconductor package in accordance with example embodiments, the protective layer structure included in the package substrate may have a multi-layered (e.g., a double-layered) structure having the first protective layer including the inorganic insulating material having a relatively high weight percent and the second protective layer including the inorganic insulating material having a relatively low weight percent, and the upper surface of the second protective layer may have a relatively low roughness. For example, the weight percent of a first inorganic insulating material in the first protective layer (with respect to the total weight of the materials in the first protective layer) may be greater than the weight percent of a second inorganic insulating material in the second protective layer (with respect to the total weight of the materials in the second protective layer). For example, the upper surface of the first protective layer may be rougher than the upper surface of the second protective layer. Thus, the underfill member that may be interposed between the semiconductor chip and the second protective layer may not be widely spread on the upper surface of the second protective layer, so that the contamination of the conductive pad adjacent to the semiconductor chip by the underfill member may be reduced (e.g., prevented) and that the semiconductor package may have enhanced electrical characteristics.

### BRIEF DESCRIPTION OF THE DRAWINGS

FIG. 1 is a cross-sectional view illustrating a package substrate in accordance with example embodiments.

FIG. 2 is an enlarged cross-sectional view of region X of FIG. 1.

FIG. 3 is a plan view illustrating the package substrate of FIG. 1.

FIG. 4 is a cross-sectional view illustrating a package substrate in accordance with example embodiments.

FIG. 5 is a cross-sectional view illustrating a semiconductor package in accordance with example embodiments.

FIG. 6 is a cross-sectional view illustrating a semiconductor package in accordance with example embodiments.

### DETAILED DESCRIPTION OF THE INVENTION

Hereinafter, example embodiments will be explained in detail with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts. As used herein, the term “and/or” includes any and all combinations of one or more of the associated listed items.

Two directions crossing each other among horizontal directions that are parallel to an upper surface and/or a lower surface of a base structure (e.g., a base structure 110) or a protective pattern structure may be referred to as first and second directions D1 and D2, respectively, and a direction perpendicular to the upper surface and/or the lower surface of the base structure or the protective pattern structure may be referred to as a third direction D3. In example embodiments, the first and second directions D1 and D2 may be perpendicular to each other.

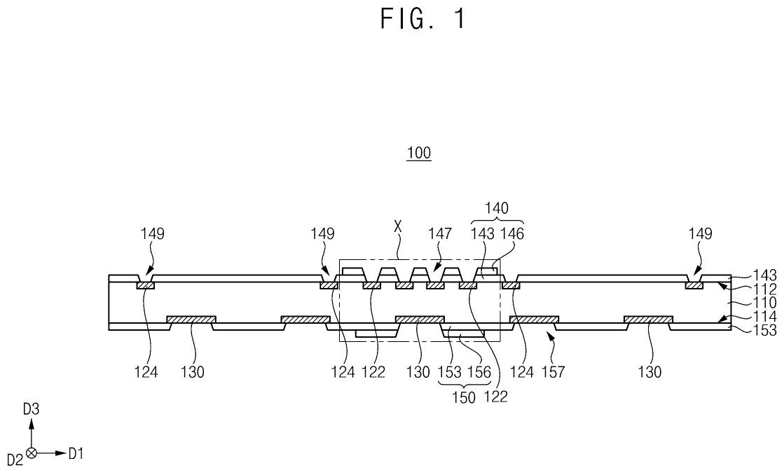

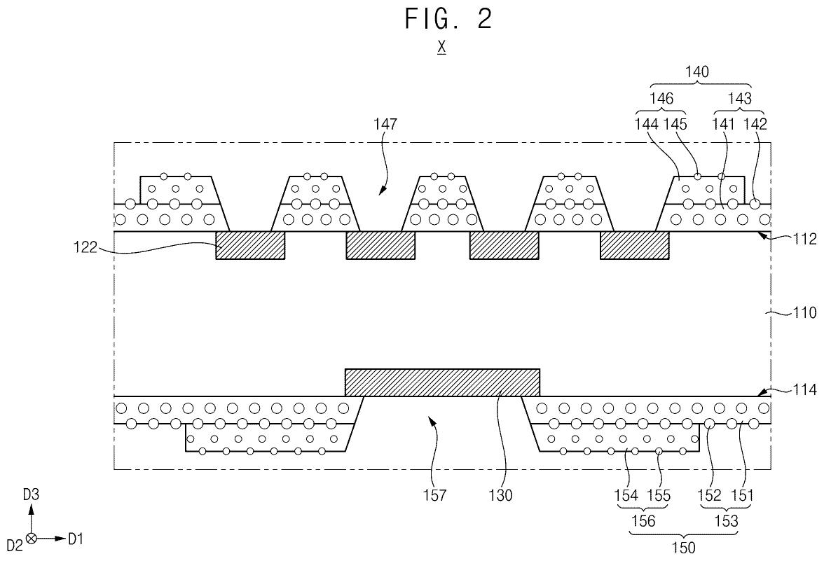

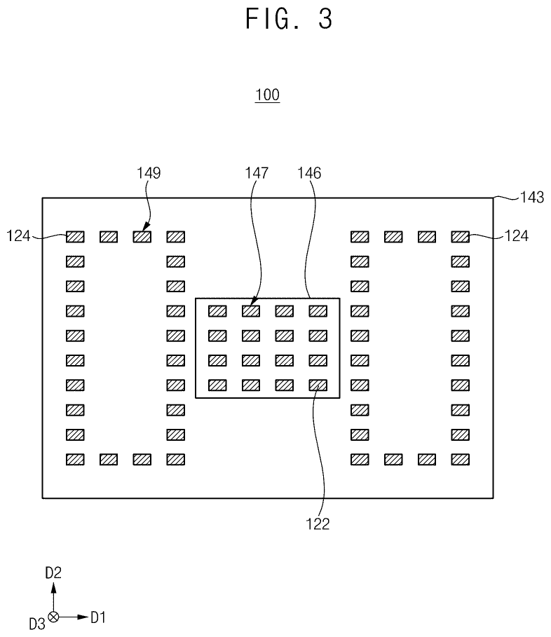

FIG. 1 is a cross-sectional view illustrating a package substrate in accordance with example embodiments, FIG. 2 is an enlarged cross-sectional view of region X of FIG. 1, and FIG. 3 is a plan view illustrating the package substrate of FIG. 1.

Referring to FIGS. 1 to 3, a package substrate 100 may include a base structure 110, first, second, and third conductive pads 122, 124 and 130, and first and second protective layer structures 140 and 150.

The base structure 110 may have first and second surfaces 112 and 114 opposite to each other in the third direction D3. The first surface 112 may be an upper surface of the base structure 110, and the second surface 114 may be a lower surface of the base structure 110. Spatially relative terms, such as “beneath,” “below,” “lower,” “under,” “above,” “upper,” and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly. For example, the first surface 112 may be a lower surface of the base structure 110, and the second surface 114 may be an upper surface of the base structure 110. In example embodiments, the base structure 110 may include an insulation layer structure and a wiring structure in the insulation layer structure.

The insulation layer structure may include insulation layers stacked in the third direction D3, and the wiring structure may include wirings, vias, conductive pads, etc., in the insulation layers. FIG. 1 shows the first, second, and third conductive pads 122, 124, and 130 among the conductive pads. However, the embodiments of the insulation layer structure and the wiring structure are not limited to the embodiments described above.

Each of the insulation layers may include an insulating material, e.g., prepreg (PPG), Ajinomoto build-up film (ABF), etc. In an example embodiment, the insulation layers may include (substantially) the same material so as to be merged with each other, and thus may not be differentiated from each other. In some embodiments, the insulation layers may include different materials from each other, or may include (substantially) the same material but a natural oxide may be formed between the insulation layers, and thus may be differentiated from each other.

Each of the first and second conductive pads 122 and 124 may be disposed adjacent to (disposed on) the first surface 112 of the base structure 110, and the third conductive pad 130 may be disposed adjacent to (disposed on) the second surface 114 of the base structure 110. A plurality of first conductive pads 122 may be spaced apart from each other in the horizontal direction (in the first direction D1 and/or the second direction D2), a plurality of second conductive pads 124 may be spaced apart from each other in the horizontal direction (in the first direction D1 and/or the second direction D2), and a plurality of third conductive pads 130 may be spaced apart from each other in the horizontal direction (in the first direction D1 and/or the second direction D2).

For example, the plurality of first conductive pads 122 may be spaced apart from each other in each of the first and second directions D1 and D2 at a central portion (e.g., a relatively central portion compared to the second conductive pads 124) of the package substrate 100 in a plan view, and the plurality of second conductive pads 124 may be spaced apart from each other in each of the first and second directions D1 and D2 at an edge portion (e.g., a relative edge portion compared to the first conductive pads 122) of the package substrate 100 in a plan view. The second conductive pads 124 may be adjacent (extend around) the first conductive pads 122 in a plan view. In an example embodiment, the second conductive pads 124 may be arranged in a shape of a rectangular ring at each of opposite sides in the first direction D1 of the first conductive pads 122, however, the inventive concept is not necessarily limited thereto.

Each of the first, second, and third conductive pads 122, 124, and 130 may include a metal, e.g., copper, aluminum, nickel, gold, etc., or a nitride thereof.

The first protective layer structure 140 may include first and second protective layers 143 and 146 sequentially stacked in the third direction D3 on the first surface 112 of the base structure 110, and each of the first and second protective layers 143 and 146 may include, e.g., solder resist (SR) containing a filler.

In example embodiments, the first protective layer 143 may include a first organic insulation structure 141 and a first inorganic insulation structure 142, and the second protective layer 146 may include a second organic insulation structure 144 and a second inorganic insulation structure 145. The first and second inorganic insulation structures 142 and 145 may serve as fillers for enhancing (e.g., increasing) stiffnesses (and/or hardness) of the first and second protective layers 143 and 146, respectively.

In example embodiments, the first organic insulation structure 141 may include a first organic insulating material, e.g., epoxy, polyimide, etc., and may have a shape of a (substantially) flat plate. In example embodiments, the first inorganic insulation structure 142 may include a first inorganic insulating material, e.g., silica, alumina, etc., and may have a (substantially) spherical shape or a (substantially) hemispherical shape.

The first inorganic insulation structure 142 may be disposed in an inside of the first organic insulation structure 141 and/or a surface (e.g., an upper surface) of the first organic insulation structure 141. As the first inorganic insulation structure 142 having the (substantially) spherical shape or a (substantially) hemispherical shape is disposed on the upper surface of the first organic insulation structure 141 having the (substantially) flat plate shape, an upper surface of the first protective layer 143 may have a first roughness.

In example embodiments, a weight percent of the first inorganic insulation structure 142 with respect to the first protective layer 143 may be equal to or greater than (about) 40%.

In example embodiments, the second organic insulation structure 144 may include a second organic insulating material, e.g., epoxy, polyimide, etc., and may have a shape of a (substantially) flat plate. The second organic insulating material may be (substantially) the same as or different from the first organic insulating material. In example embodiments, the second inorganic insulation structure 145 may include a second inorganic insulating material, e.g., silica, alumina, etc., and may have a (substantially) spherical shape or a (substantially) hemispherical shape. The second inorganic insulating material may be (substantially) the same as or different from the first inorganic insulating material.

The second inorganic insulation structure 145 may be disposed in an inside of the second organic insulation structure 144 and/or on a surface (e.g., an upper surface) of the second organic insulation structure 144. As the second inorganic insulation structure 145 having the (substantially) spherical shape and/or the (substantially) hemispherical shape is disposed on the upper surface of the second organic insulation structure 144 having the (substantially) flat plate shape, an upper surface of the second protective layer 146 may have a second roughness.

In example embodiments, a weight percent of the second inorganic insulation structure 145 with respect to the second protective layer 146 may be less than (about) 40%. That is, the weight percent of the second inorganic insulation structure 145 having the (substantially) spherical shape and/or the (substantially) hemispherical shape with respect to the second protective layer 146 may be less than the weight percent of the first inorganic insulation structure 142 having the (substantially) spherical shape and/or the (substantially) hemispherical shape with respect to the first protective layer 143, and thus the second roughness of the upper surface of the second protective layer 146 may be less than the first roughness of the upper surface of the first protective layer 143. For example, the upper surface of the first protective layer 143 may be rougher than the upper surface of the second protective layer 146. The term, roughness, herein may mean a degree of a deviation of a surface. For example, roughness may mean an average value of the peaks and valleys of (a portion of) a surface, a difference between the highest peak and the lowest valley of (a portion of) a surface, and/or a root mean-square deviation of (a portion of) a surface. However, the definition of roughness is not limited to the definitions described above.

In example embodiments, the first and second inorganic insulation structures 142 and 145 may have stiffnesses (and/or hardnesses) greater than those of the first and second organic insulation structures 141 and 144, respectively. Thus, the first protective layer 143 including the first inorganic insulation structure 142 having a relatively high weight percent may have a stiffness (and/or a hardness) greater than that of the second protective layer 146 including the second inorganic insulation structure 145 having a relatively low weight percent. For example, the weight percent of the first inorganic insulation structure 142 in the first protective layer 143 (with respect to the total weight of the first protective layer 143) may be greater than the weight percent of the second inorganic insulation structure 145 in the second protective layer 146 (with respect to the total weight of the second protective layer 146).

In example embodiments, the first protective layer 143 may be disposed on an entire portion of the first surface 112 of the base structure 110, and the second protective layer 146 may be disposed on a portion of the upper surface of the first protective layer 143. For example, the second protective layer 146 may be disposed at a (relatively) central portion of the first protective layer 143 in a plan view, however, the inventive concept is not necessarily limited thereto.

In example embodiments, the first protective layer structure 140 may include first and second openings 147 and 149 exposing upper surfaces of the first and second conductive pads 122 and 124, respectively. The first opening 147 may extend into (e.g., extend through or penetrate) the first and second protective layers 143 and 146, and may expose an upper surface of the first conductive pad 122. The second opening 149 may extend into (e.g., extend through or penetrate) the first protective layer 143, and may expose an upper surface of the second conductive pad 124.

The second protective layer structure 150 may include third and fourth protective layers 153 and 156 sequentially stacked in the third direction D3 on the second surface 114 of the base structure 110, and each of the third and fourth protective layers 153 and 156 may include, e.g., SR containing a filler.

In example embodiments, the third protective layer 153 may include a third organic insulation structure 151 and a third inorganic insulation structure 152, and the fourth protective layer 156 may include a fourth organic insulation structure 154 and a fourth inorganic insulation structure 155. The third and fourth inorganic insulation structures 152 and 155 may serve as fillers for enhancing (e.g., increasing) stiffnesses (and/or hardness) of the third and fourth protective layers 153 and 156, respectively.

In example embodiments, the third organic insulation structure 151 may include a third organic insulating material, e.g., epoxy, polyimide, etc., and may have a shape of a (substantially) flat plate. The third organic insulating material may be (substantially) the same as or different from the first and second organic insulating materials. In example embodiments, the third inorganic insulation structure 152 may include a third inorganic insulating material, e.g., silica, alumina, etc., and may have a (substantially) spherical shape or a (substantially) hemispherical shape. The third inorganic insulating material may be (substantially) the same as or different from the first and second inorganic insulating materials.

The third inorganic insulation structure 152 may be disposed in an inside of the third organic insulation structure 151 and/or on a surface (e.g., a lower surface of the third organic insulation structure 151). As the third inorganic insulation structure 152 having the (substantially) spherical shape and/or a (substantially) hemispherical shape is disposed on the lower surface of the third organic insulation structure 151 having the (substantially) flat plate shape, a lower surface of the third protective layer 153 may have a third roughness.

In example embodiments, a weight percent of the third inorganic insulation structure 152 with respect to the third protective layer 153 may be equal to or more than (about) 40%.

In example embodiments, the fourth organic insulation structure 154 may include a fourth organic insulating material, e.g., epoxy, polyimide, etc., and may have a shape of a (substantially) flat plate. The fourth organic insulating material may be (substantially) the same as or different from the third organic insulating material. In example embodiments, the fourth inorganic insulation structure 155 may include a second inorganic insulating material, e.g., silica, alumina, etc., and may have a (substantially) spherical shape or a (substantially) hemispherical shape. The fourth inorganic insulating material may be (substantially) the same as or different from the third inorganic insulating material.

The fourth inorganic insulation structure 155 may be disposed in an inside of the fourth organic insulation structure 154 and/or on a surface (e.g., a lower surface) of the fourth organic insulation structure 154. As the fourth inorganic insulation structure 155 having the (substantially) spherical shape and/or the (substantially) hemispherical shape is disposed on the lower surface of the fourth organic insulation structure 154 having the (substantially) flat plate shape, a lower surface of the fourth protective layer 156 may have a fourth roughness.

In example embodiments, a weight percent of the fourth inorganic insulation structure 155 with respect to the fourth protective layer 156 may be less than (about) 40%. That is, the weight percent of the fourth inorganic insulation structure 155 having the (substantially) spherical shape and/or the (substantially) hemispherical shape with respect to the fourth protective layer 156 may be less than the weight percent of the third inorganic insulation structure 152 having the (substantially) spherical shape and/or the (substantially) hemispherical shape with respect to the third protective layer 153, and thus the fourth roughness of the lower surface of the fourth protective layer 156 may be less than the third roughness of the lower surface of the third protective layer 153. For example, the lower surface of the third protective layer 153 may be rougher than the lower surface of the fourth protective layer 156.

In example embodiments, the third and fourth inorganic insulation structures 152 and 155 may have stiffnesses (and/or hardness) greater than those of the third and fourth organic insulation structures 151 and 154, respectively. Thus, the third protective layer 153 including the third inorganic insulation structure 152 having a relatively high weight percent may have a stiffness (and/or a hardness) greater than that of the fourth protective layer 156 including the fourth inorganic insulation structure 155 having a relatively low weight percent. For example, the weight percent of the third inorganic insulation structure 152 in the third protective layer 153 (with respect to the total weight of the third protective layer 153) may be greater than the weight percent of the fourth inorganic insulation structure 155 in the fourth protective layer 156 (with respect to the total weight of the fourth protective layer 156).

In example embodiments, the third protective layer 153 may be disposed on an entire portion of the second surface 114 of the base structure 110, and the fourth protective layer 156 may be disposed on a portion of the lower surface of the third protective layer 153. For example, the fourth protective layer 156 may be disposed at a (relatively) central portion of the third protective layer 153 in a plan view, however, the inventive concept is not necessarily limited thereto.

In example embodiments, the fourth protective layer 156 may at least partially overlap the second protective layer 146 in the third direction D3.

In example embodiments, the second protective layer structure 150 may include third openings 157 exposing lower surfaces of the third conductive pads 130, respectively. Some of the third opening 157 may extend into (e.g., extend through or penetrate) the third and fourth protective layers 153 and 156, and may expose a lower surface of the third conductive pad 130. Some of the third openings 157 may extend into (e.g., extend through or penetrate) the third protective layer 153, and may expose a lower surface of the third conductive pad 130.

In the package substrate 100 in accordance with example embodiments, the first protective layer structure 140 on the first surface 112 of the base structure 110 may have a multi-layered structure in which the first protective layer 143 including the first inorganic insulation structure 142 having a relatively high weight percent and the second protective layer 146 including the second inorganic insulation structure 145 having a relatively low weight percent are stacked in the third direction D3.

As the upper surface of the second protective layer 146 may have a relatively low roughness, and thus, after a semiconductor chip is mounted on the second protective layer 146, when an underfill member is formed between the upper surface of the second protective layer 146 and a lower surface of the semiconductor chip, the underfill member may be less spread (e.g., may not be spread).

For example, if the underfill member is formed on a protective layer including an inorganic insulating material having a weight percent of equal to or greater than (about) 40%, an upper surface of the protective layer may have a high roughness and a contact area between the underfill member and the protective layer may increase, so that the underfill member may be widely spread. Thus, the underfill member may contact and contaminate the upper surface of the second conductive pad 124, which contacts a bonding wire for electrical connection to the semiconductor chip and is disposed adjacent to the first surface 112 of the base structure 110.

However, in example embodiments, the first protective layer structure 140 may include the second protective layer 146 including the second inorganic insulation structure 145 having the relatively low weight percent on the first protective layer 143 including the first inorganic insulation structure 142 having the relatively high weight percent, and thus the underfill member may contact the upper surface of the second protective layer 146 having a relatively low roughness so that a contact area between the underfill member and the first protective layer structure 140 may decrease. Accordingly, the underfill member may not be widely spread, and the upper surface of the second conductive pad 124, which contacts the bonding wire and is disposed adjacent to the first surface 112 of the base structure 110, may be protected better (e.g., may be prevented) from being contaminated by the underfill member.

The first protective layer structure 140 may include not only the second protective layer 146, but also the first protective layer 143 including the first inorganic insulation structure 142 having the relatively high weight percent, and the first protective layer structure 140 may be disposed on the entire portion of the first surface 112 of the base structure 110, so that the package substrate 100 may have an enhanced (e.g., increased) stiffness (and/or hardness).

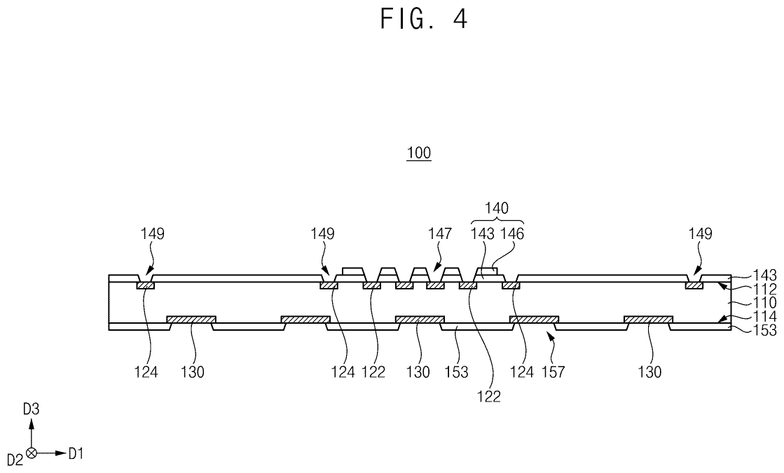

FIG. 4 is a cross-sectional view illustrating a package substrate in accordance with example embodiments, which may correspond to FIG. 1. This package substrate may be substantially the same as or similar to that of FIGS. 1 to 3, except for the second protective layer structure, and thus repeated explanations may be omitted herein.

Referring to FIG. 4, the second protective layer structure 150 may include the third protective layer 153, but may not include the fourth protective layer 156.

No semiconductor chip may be disposed on the lower surface of the second protective layer structure 150, and thus no underfill member may be disposed thereon, so that the second protective layer structure 150 may not include the fourth protective layer 156 having a relatively low roughness.

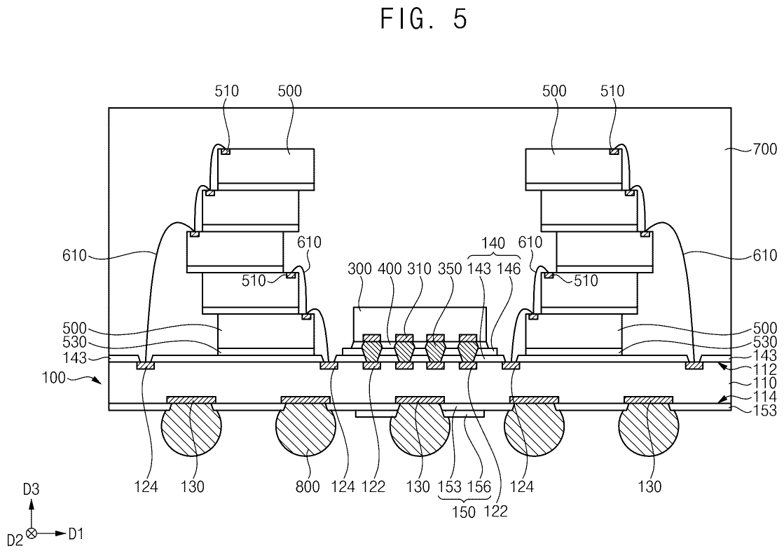

FIG. 5 is a cross-sectional view illustrating a semiconductor package in accordance with example embodiments. The semiconductor package substrate may include the package substrate of FIGS. 1 to 3, and thus repeated explanations thereof may be omitted herein. However, the semiconductor package may also include the package substrate of FIG. 4.

Referring to FIG. 5, the semiconductor package may include the package substrate 100, first and second semiconductor chips 300 and 500, first and second conductive connection members 350 and 800, an underfill member 400, a bonding layer 530, a bonding wire 610 and a molding member 700.

The first semiconductor chip 300 may be a logic chip including logic device. A fourth conductive pad 310 may be disposed on a lower surface of the first semiconductor chip 300, and the first conductive connection member 350 may be electrically connected to (e.g., may contact) the fourth conductive pad 310 and the first conductive pad 122 of the package substrate 100. In example embodiments, a plurality of fourth conductive pads 310 may be spaced apart from each other in each of the first and second directions D1 and D2, and a plurality of first conductive connection members 350 may also be spaced apart from each other in each of the first and second directions D1 and D2.

The first conductive connection member 350 may extend into (e.g., extend through or penetrate) the first and second protective layers 143 and 146 included in the first protective layer structure 140, and may be electrically connected to (e.g., may contact) the upper surface of the first conductive pad 122 and a lower surface of the fourth conductive pad 310. The first conductive connection member 350 may include a conductive bump or a conductive ball including, e.g., solder.

The underfill member 400 may be disposed between the upper surface of the second protective layer 146 and the lower surface of the first semiconductor chip 300, and may extend around (e.g., cover) an upper sidewall of the first conductive connection member 350. In example embodiments, the underfill member 400 may have a sidewall slanted with respect to the upper surface of the package substrate 100. In example embodiments, the underfill member 400 may have a planar area smaller than that of the second protective layer 146, and may be disposed in a region in which the second protective layer 146 is formed in a plan view. The underfill member 400 may overlap the second protective layer 146 in the third direction D3.

The underfill member 400 may include, e.g., epoxy or polymer.

The second semiconductor chip 500 may be a memory chip including a memory device. In example embodiments, a plurality of second semiconductor chips 500 may be stacked in the third direction D3.

A fifth conductive pad 510 may be disposed at an upper portion of the second semiconductor chip 500, and the bonding wire 610 may be electrically connected to (e.g., may contact) the fifth conductive pad 510 and the second conductive pad 124 of the package substrate 100. In example embodiments, a plurality of fifth conductive pads 510 may be spaced apart from each other in each of the first and second directions D1 and D2 in the second semiconductor chip 500, and a plurality of bonding wires 610 may also be spaced apart from each other in each of the first and second directions D1 and D2. The second conductive pad 124 may not overlap the first and second semiconductor chips 300 and 500, the underfill member 400, and the second protective layer 146 in the third direction D3.

The bonding wire 610 may include a metal, e.g., gold, aluminum, copper, etc.

The bonding layer 530 may be attached to a lower surface of a first one of the second semiconductor chips 500, and may contact the upper surface of the first protective layer structure 140 of the package substrate 100, or an upper surface of a second one of the second semiconductor chips 500 that is disposed under the first one of the second semiconductor chips 500. The bonding layer 530 may include, e.g., die attach film (DAF), non-conductive film (NCF), non-conductive paste (NCP), etc.

The molding member 700 may be disposed on the package substrate 100, and may be on (e.g., cover or overlap) the first and second semiconductor chips 300 and 500, the underfill member 400, the bonding layer 530, and the bonding wire 610. The molding member 700 may include, e.g., epoxy molding compound (EMC).

The second conductive connection member 800 may be disposed on the lower surface of the second protective layer structure 150 of the package substrate 100, and may extend into (e.g., extend through or penetrate) the second protective layer structure 150 to be electrically connected to (to contact) the lower surface of the third conductive pad 130. The second conductive connection member 800 may include a conductive bump or a conductive ball including, e.g., solder.

In the semiconductor package, the underfill member 400 may be interposed between the second protective layer 146 of the first protective layer structure 140 in the package substrate 100 and the first semiconductor chip 300, and as the upper surface of the second protective layer 146 has the relatively low roughness, the underfill member 400 may not be widely spread on the upper surface of the second protective layer 146. Thus, the underfill member 400 may less permeate (e.g., may not permeate) into and may less contaminate (e.g., may not contaminate) the upper surface of the second conductive pad 124 adjacent to the first semiconductor chip 300, so that the semiconductor package may have enhanced electrical characteristics.

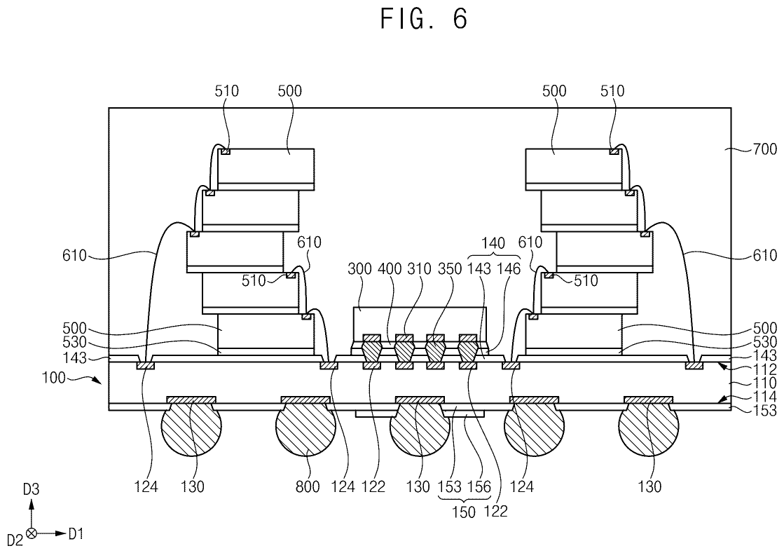

FIG. 6 is a cross-sectional view illustrating a semiconductor package in accordance with example embodiments, which may correspond to FIG. 5. This semiconductor package substrate may be substantially the same as or similar to that of FIG. 5, except for the second protective layer, and thus repeated explanations may be omitted herein.

Referring to FIG. 6, the second protective layer 146 may have a planar area (substantially) the same as that of the underfill member 400, and a sidewall of the second protective layer 146 may be aligned with a sidewall of the lower surface of the underfill member 400 in the third direction D3.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A package substrate comprising:
a base structure having a first surface and a second surface that are opposite to each other in a direction that is perpendicular to the first surface and the second surface;
a first protective layer on the first surface of the base structure, wherein the first protective layer includes a first organic insulation structure and a first inorganic insulation structure, and wherein the first organic insulation structure includes a first organic insulating material, and the first inorganic insulation structure includes a first inorganic insulating material; and
a second protective layer on an upper surface of a portion of the first protective layer, wherein the second protective layer includes a second organic insulation structure and a second inorganic insulation structure, and wherein the second organic insulation structure includes a second organic insulating material, and the second inorganic insulation structure includes a second inorganic insulating material,
wherein a weight percent of the second inorganic insulating material with respect to the second protective layer is less than a weight percent of the first inorganic insulating material with respect to the first protective layer.

2. The package substrate according to claim 1, wherein the weight percent of the second inorganic insulating material with respect to the second protective layer is less than 40%, and the weight percent of the first inorganic insulating material with respect to the first protective layer is equal to or greater than 40%.

3. The package substrate according to claim 1, wherein each of the first and second organic insulating materials includes epoxy and/or polyimide, and each of the first and second inorganic insulating materials includes silica and/or alumina.

4. The package substrate according to claim 1, wherein the first and second organic insulating materials are a same material, and the first and second inorganic insulating materials are a same material.

5. The package substrate according to claim 1, wherein the first and second organic insulating materials are different materials from each other, and the first and second inorganic insulating materials are different materials from each other.

6. The package substrate according to claim 1, wherein each of the first and second organic insulation structures has a shape of a flat plate, and each of the first and second inorganic insulation structures has a spherical shape and/or a hemispherical shape.

7. The package substrate according to claim 1, wherein the second protective layer is at a central portion of the first protective layer in a plan view.

8. The package substrate according to claim 1, further comprising a third protective layer on the second surface of the base structure, wherein the third protective layer includes a third organic insulation structure and a third inorganic insulation structure, and wherein the third organic insulation structure incudes a third organic insulating material, and the third inorganic insulation structure includes a third inorganic insulating material.

9. The package substrate according to claim 8, further comprising a fourth protective layer on a lower surface of a portion of the third protective layer, wherein the fourth protective layer includes a fourth organic insulation structure and a fourth inorganic insulation structure, and wherein the fourth organic insulation structure includes a fourth organic insulating material, and the fourth inorganic insulation structure includes a fourth inorganic insulating material,
wherein a weight percent of the fourth inorganic insulating material with respect to the fourth protective layer is less than a weight percent of the third inorganic insulating material with respect to the third protective layer.

10. The package substrate according to claim 9, wherein each of the third and fourth organic insulating materials includes epoxy and/or polyimide, and each of the third and fourth inorganic insulating materials includes silica and/or alumina.

11. A package substrate comprising:
a base structure having a first surface and a second surface that are opposite to each other in a direction that is perpendicular to the first surface and the second surface;
a first protective layer on the first surface of the base structure, wherein the first protective layer includes a first organic insulation structure and a first inorganic insulation structure, and wherein the first organic insulation structure includes a first organic insulating material, and the first inorganic insulation structure includes a first inorganic insulating material; and
a second protective layer on an upper surface of a portion of the first protective layer, wherein the second protective layer includes a second organic insulation structure and a second inorganic insulation structure, and wherein the second organic insulation structure includes a second organic insulating material, and the second inorganic insulation structure includes a second inorganic insulating material,
wherein a roughness of an upper surface of the second protective layer is less than a roughness of an upper surface of the first protective layer.

12. The package substrate according to claim 11, wherein each of the first and second organic insulating materials includes epoxy and/or polyimide, and each of the first and second inorganic insulating materials includes silica and/or alumina.

13. The package substrate according to claim 11, wherein the first and second organic insulating materials are a same material, and the first and second inorganic insulating materials are a same material.

14. The package substrate according to claim 11, wherein each of the first and second organic insulation structures has a shape of a flat plate, and each of the first and second inorganic insulation structures has a spherical shape and/or a hemispherical shape.

15. A semiconductor package comprising:
a package substrate including:
a base structure having a first surface and a second surface that are opposite to each other in a direction that is perpendicular to the first surface and the second surface;
a first protective layer on the first surface of the base structure, wherein the first protective layer includes a first organic insulation structure and a first inorganic insulation structure, and wherein the first organic insulation structure includes a first organic insulating material, and the first inorganic insulation structure includes a first inorganic insulating material; and
a second protective layer on an upper surface of a portion of the first protective layer, wherein the second protective layer includes a second organic insulation structure and a second inorganic insulation structure, wherein the second organic insulation structure includes a second organic insulating material, and the second inorganic insulation structure includes a second inorganic insulating material,
wherein a weight percent of the second inorganic insulating material with respect to the second protective layer is less than a weight percent of the first inorganic insulating material with respect to the first protective layer, and
wherein a roughness of an upper surface of the second protective layer is less than a roughness of an upper surface of the first protective layer;
a first semiconductor chip on the package substrate;
an underfill member between the upper surface of the second protective layer and a lower surface of the first semiconductor chip; and
a molding member on the first semiconductor chip and the underfill member.

16. The semiconductor package according to claim 15, wherein a planar area of the second protective layer is greater than a planar area of the underfill member, and
wherein the underfill member overlaps the second protective layer in the direction that is perpendicular to the first surface and the second surface of the base structure.

17. The semiconductor package according to claim 15, wherein the base structure includes a first conductive pad adjacent to the first surface, and the first semiconductor chip includes a second conductive pad adjacent to the lower surface of the first semiconductor chip,
wherein the semiconductor package further comprises a conductive connection member extending into the first and second protective layers and electrically connecting an upper surface of the first conductive pad and a lower surface of the second conductive pad, and
wherein the underfill member extends around an upper sidewall of the conductive connection member.

18. The semiconductor package according to claim 17, wherein the base structure further includes a third conductive pad adjacent to the first surface, the third conductive pad being spaced apart from the first conductive pad,
wherein the semiconductor package further comprises:
a second semiconductor chip spaced apart from the first semiconductor chip on the package substrate, the second semiconductor chip including a fourth conductive pad adjacent to an upper surface of the second semiconductor chip; and
a bonding wire electrically connecting an upper surface of the third conductive pad and an upper surface of the fourth conductive pad, and
wherein the molding member is on the second semiconductor chip and the bonding wire.

19. The semiconductor package according to claim 15, wherein the package substrate further includes:
a third protective layer on the second surface of the base structure, wherein the third protective layer includes a third organic insulation structure and a third inorganic insulation structure, and wherein the third organic insulation structure includes a third organic insulating material, and the third inorganic insulation structure includes a third inorganic insulating material; and
a fourth protective layer on a lower surface of a portion of the third protective layer, wherein the fourth protective layer includes a fourth organic insulation structure and a fourth inorganic insulation structure, and wherein the fourth organic insulation structure includes a fourth organic insulating material, and the fourth inorganic insulation structure includes a fourth inorganic insulating material,
wherein a weight percent of the fourth inorganic insulating material with respect to the fourth protective layer is less than a weight percent of the third inorganic insulating material with respect to the third protective layer.

20. The semiconductor package according to claim 19, wherein the base structure includes a conductive pad adjacent to the second surface, and
wherein the semiconductor package further comprises a conductive connection member extending into the third and fourth protective layers and electrically connecting a lower surface of the conductive pad.
